(19) United States
(12) Patent Application Publication
(10) Pub. No.: US 2007/0202633 A1
(43) Pub. Date: Aug. 30, 2007

(54) Semiconductor package and method for fabricating the same

(75) Inventors: Wen-Tsung Tseng, Taichung (TW); Fang-Lin Tsai, Taichung (TW); Ho-Yi Tsai, Taichung Hsien (TW); Cheng-Hsu Hsiao, Taichung Hsien (TW); Chih-Ming Huang, Hsinchu Hsein (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/651,708

(22) Filed: Jan. 9, 2007

(30) Foreign Application Priority Data
Feb. 27, 2006 (TW) 095106557

(51) Int. Cl. H01L 21/00

(52) U.S. Cl. 438/122

(57) ABSTRACT

A semiconductor package and a method for fabricating the same are provided. The method includes providing a substrate having recognition points and a heat sink having openings, and placing the heat sink on the substrate with the recognition points being exposed through the openings; using a checking system to inspect the recognition points through the openings so as to ensure that the heat sink is placed at a predetermined position on the substrate; and attaching the heat sink to the substrate via an adhesive. By the above semiconductor package and method, there is no need to form positioning holes in the substrate such that any adverse effect on the circuit layout and reliability of the semiconductor package is avoided, and any positional shifting of the heat sink relative to the substrate can be determined in a real time manner.

### FIELD OF THE INVENTION

The present invention relates to semiconductor packages and fabrication methods thereof, and more particularly, to a semiconductor package integrated with a heat sink and a method for fabricating the semiconductor package.

### BACKGROUND OF THE INVENTION

Heat dissipation is considered as a factor of concern affecting the performance of a chip mounted in a semiconductor package. Due to high integration of the chip with more and more electronic circuits and electronic components incorporated therein, an amount of heat produced during the operation of the chip is accordingly increased. In the semiconductor package, an encapsulant used for encapsulating the chip is made of a resin having poor thermal conductivity and is thus not efficient in dissipating the heat. As a result, the chip may not function properly due to overheat or heat accumulation.

In order to improve the heat dissipating efficiency for the semiconductor package, there has been proposed a method of additionally incorporating a heat sink into the semiconductor package, as disclosed in U.S. Pat. No. 6,552,428. As shown in FIG. 1, a heat sink 14 is attached via an adhesive 13 to a substrate 12 on which a chip 11 is mounted. The heat sink 14 comprises supporting portions 141 and a flat portion 142 integrally connected thereto. The supporting portions 141 elevate the flat portion 142 to a predetermined height such that the flat portion 142 does not interfere with the chip 11 mounted on the substrate 12, and the chip 11 can be received in a space between the flat portion 142 and the substrate 12. However, during a process of attaching the heat sink 14 to the substrate 12, the heat sink 14 may be shifted in position or dislocated before the adhesive 13 is cured due to vibration from or improper operation of the process equipment. As such, when the adhesive 13 is cured, the heat sink 14 is not properly attached to a predetermined position on the substrate 12 and may come into contact with gold wires 15 used for electrically connecting the chip 11 to the substrate 12, thereby leading to a reliability issue of the semiconductor package.

Accordingly, U.S. Pat. No. 6,528,876 provides a solution to the foregoing problem by using another method for integrating a heat sink into the semiconductor package. As shown in FIG. 2, a plurality of positioning holes 221 are formed in a substrate 22 on which a chip 21 is mounted, and an adhesive 23 is applied into the positioning holes 221. A heat sink 24 comprising supporting portions 241 and a flat portion 242 connected thereto is attached to the substrate 22 via the adhesive 23, wherein the supporting portions 241 are formed with protrusions 2411 corresponding to the positioning holes 221 of the substrate 22, such that the protrusions 2411 are engaged with the positioning holes 221 and the flat portion 242 is thus elevated by the supporting portions 241.

The above method advantageously allows the heat sink 24 to be firmly attached to the substrate 22 and held in position without being shifted and coming into contact with gold wires 25. However, the need of forming the positioning holes 221 in the substrate 22 adversely affects the circuit layout and reliability of the semiconductor package.

Another solution is provided by Taiwan Patent No. I231018 in which location pins are used to secure a heat sink in position on a substrate. As shown in FIGS. 3A and 3B, a plurality of through holes 311 are formed in a substrate 31, and correspondingly a plurality of openings 3211 are formed in supporting portions 321 of a heat sink 32, such that the heat sink 32 can be held in place on the substrate 31 by allowing location pins 331 formed on a lower mold 33 to be inserted into both the through holes 311 and the openings 3211. However, this method still needs the substrate to be formed with holes therein, thereby adversely affecting the circuit layout and reliability of the semiconductor package. Further, the use of a lower mold with location pins undesirably increases cost of the process equipment and complexity of the fabrication processes for the semiconductor package.

### SUMMARY OF THE INVENTION

In view of the foregoing drawbacks in the prior art, a primary objective of the present invention is to provide a semiconductor package and a method for fabricating the same, which can determine whether a heat sink is shifted in position without the need of forming holes in a substrate.

Another objective of the present invention is to provide a semiconductor package and a method for fabricating the same, which can check whether a heat sink is precisely positioned in a real time manner.

A further objective of the present invention is to provide a semiconductor package and a method for fabricating the same, which can determine whether a heat sink is placed at a predetermined position on a substrate before attaching the heat sink to the substrate, and also determine whether the heat sink is shifted in position after the heat sink is attached to the substrate by an adhesive.

To achieve the above and other objectives, the present invention provides a method for fabricating a semiconductor package. The method comprises the steps of: providing a substrate and a heat sink, and placing the heat sink on the substrate, wherein the substrate is formed with a plurality of recognition points thereon and the heat sink has a plurality of openings through which the recognition points are exposed; using a checking system to inspect the recognition points on the substrate through the openings of the heat sink, so as to ensure that the heat sink is placed at a predetermined position on the substrate; and attaching the heat sink to the substrate via an adhesive. The substrate is mounted with a chip thereon.

By the above method, the present invention also proposes a semiconductor package, comprising: a substrate formed with a plurality of recognition points thereon; and a heat sink having a plurality of openings and mounted on the substrate, wherein the recognition points on the substrate are exposed through the openings of the heat sink. The substrate is mounted with a chip thereon.

In the semiconductor package and the method for fabricating the same according to the present invention, there is no need to form holes in the substrate or performing any other destructive process on the substrate, such that the circuit layout and reliability of the semiconductor package are not affected. Further in the present invention, the checking system is used to check the recognition points on the substrate through the openings of the heat sink so as to obtain a status of positioning the heat sink on the substrate. This allows the positional checking to be performed in a real time manner before the heat sink is completely adhered to the substrate, such that the accuracy and success of attaching the heat sink to a predetermined position on the substrate are improved.

### BRIEF DESCRIPTION OF DRAWINGS

The present invention can be more fully understood by reading the following detailed description of the preferred embodiments, with reference made to the accompanying drawings, wherein:

FIG. 1 (PRIOR ART) is a cross-sectional view of a semiconductor package having a heat sink attached to a substrate by an adhesive as disclosed in U.S. Pat. No. 6,552,428;

FIG. 2 (PRIOR ART) is a cross-sectional view of a semiconductor package disclosed in U.S. Pat. No. 6,528,876, wherein a heat sink is attached to a substrate by engaging protrusions of the heat sink with positioning holes of the substrate;

FIGS. 3A and 3B (PRIOR ART) are cross-sectional diagrams showing a method of using location pins to secure a heat sink in position on a substrate as disclosed in Taiwanese Patent No. I231018;

FIGS. 4A to 4H are schematic diagrams showing a semiconductor package and a method for fabricating the same in accordance with a first preferred embodiment of the present invention; and

FIG. 5 is a top view of a semiconductor package in accordance with a second preferred embodiment of the present invention.

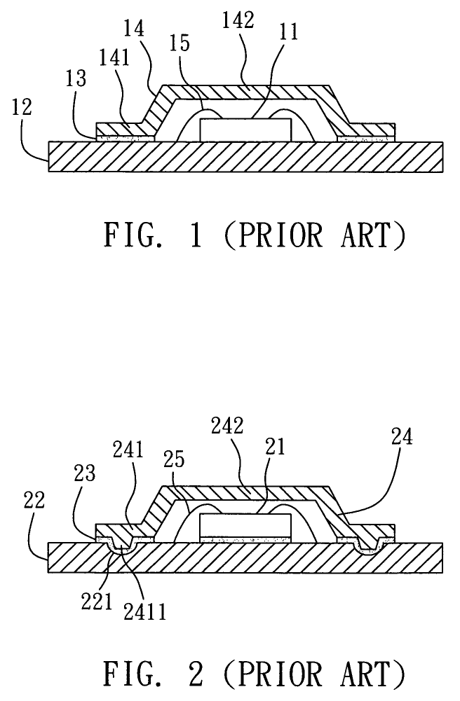

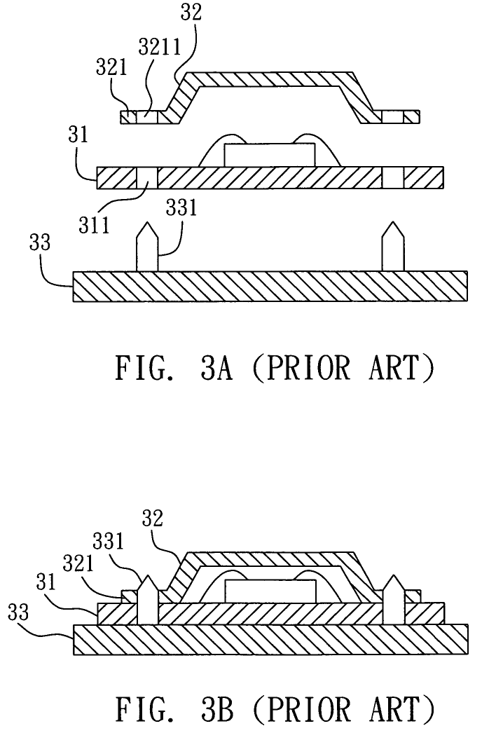

### DETAILED DESCRIPTION OF THE PREFERRED EMBODIMENTS

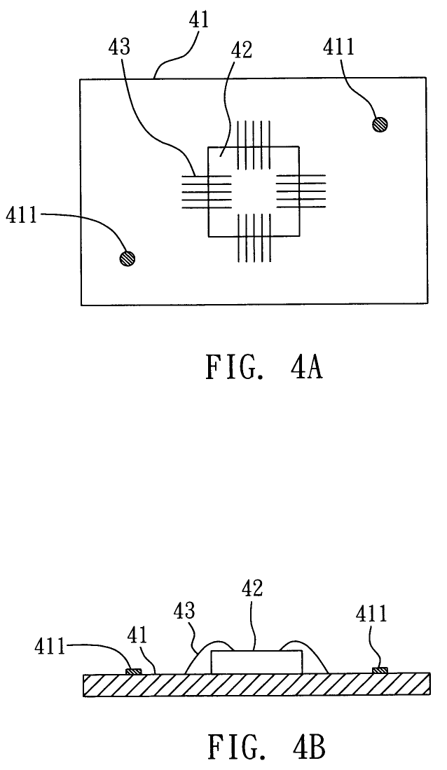

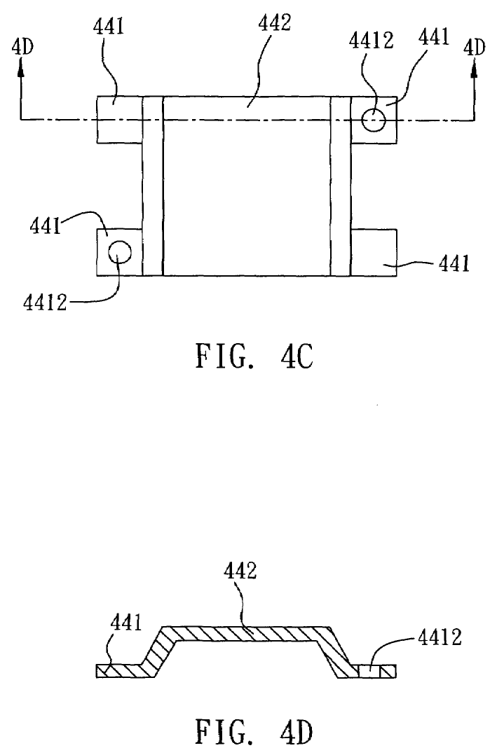

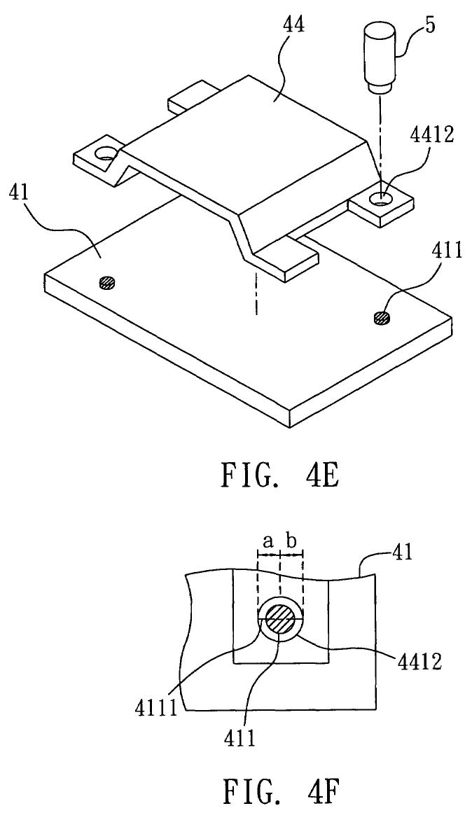

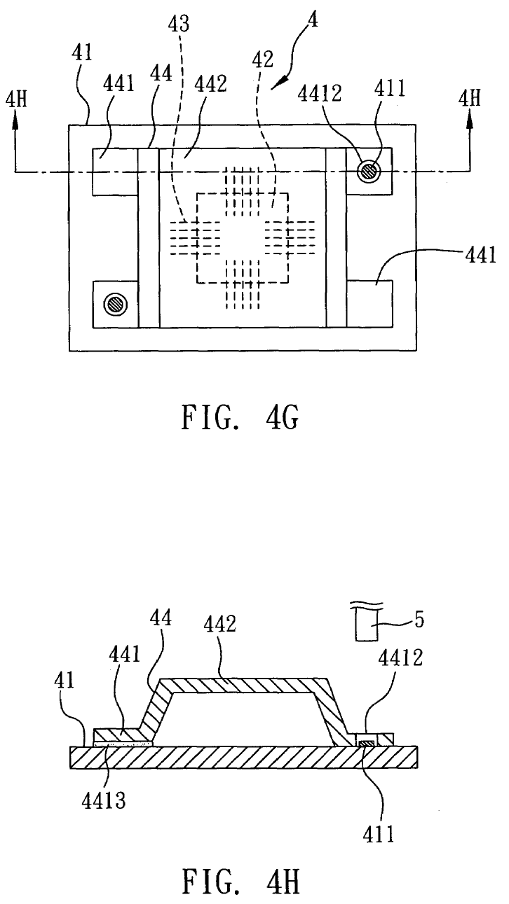

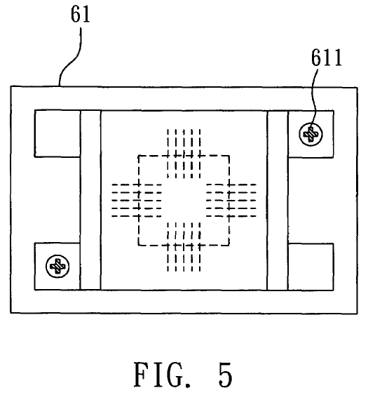

Preferred embodiments of a semiconductor package and a method for fabricating the same as proposed in the present invention are described as follows with reference to FIGS. 4A to 4H and FIG. 5. It should be understood that the drawings are simplified schematic diagrams only showing the elements relevant to the present invention, and the layout of elements could be more complicated in practical implementation.

### First Preferred Embodiment

FIGS. 4A to 4H are schematic diagrams showing the semiconductor package and the method for fabricating the same in accordance with a first preferred embodiment of the present invention.

As shown in FIGS. 4A and 4B, a substrate 41 is provided, which is formed with a plurality of recognition points 411 thereon. The recognition points 411 can be shaped as round dots and can be formed by electroplating a metal (such as gold) on the substrate 41. A chip 42 is mounted on the substrate 41 and is electrically connected to the substrate 41 by bonding wires such as gold wires 43. Alternatively, the chip 42 may be mounted on and electrically connected to the substrate 41 by a flip-chip technique.

As shown in FIGS. 4C and 4D, a heat sink 44 is provided. The heat sink 44 comprises a flat portion 442, and a plurality of supporting portions 441 integrally connected to the flat portion 442 and elevating the flat portion 442 to a predetermined height. The supporting portions 441 are formed with openings 4412 therein, wherein the openings 4412 can be located at opposite positions or diagonal positions, and FIG. 4C shows the openings 4412 being positioned diagonally.

FIG. 4D is a cross-sectional view of FIG. 4C taken along line 4D-4D. As shown in FIG. 4D, the supporting portions 441 and the flat portion 442 of the heat sink 44 are integrally connected together and form a space under the flat portion 442 such that when the heat sink 44 is placed on the substrate 41, the chip 42 can be received in the space under the flat portion 442.

Referring to FIGS. 4E and 4F, a checking system 5 is employed to inspect the recognition points 411 on the substrate 41 through the openings 4412 of the heat sink 44 after the heat sink 44 is placed on the substrate 41 with the recognition points 411 being exposed through the openings 4412, so as to determine relative positions of the openings 4412 and the recognition points 411 and thus obtain a status of positioning the heat sink 44 on the substrate 41. The checking system 5 can be a charge coupled device (CCD). Images obtained by the checking system 5 represent superimposition images of the recognition points 411 and the openings 4412, which can be used to determine a horizontal positioning status of the heat sink 44 on the substrate 41. This is achieved by extending a horizontal diameter 4111 of any one of the recognition points 411 to the perimeter of a corresponding one of the openings 4412 so as to obtain distances a and b, wherein the distance a represents a left-hand distance from a center of the recognition point 411 to the perimeter of the corresponding opening 4412 and the distance b represents a right-hand distance from the center of the recognition point 411 to the perimeter of the corresponding opening 4412 as shown in FIG. 4F, such that a horizontal eccentric distance can be calculated as |(a−b)/2| and is used to determine the extent of horizontal shifting of the heat sink 44 relative to the substrate 41. By a similar method as above, a perpendicular positioning status of the heat sink 44 can be determined using a perpendicular diameter of any one of the recognition points 411, which is perpendicular to the horizontal diameter 4111, to obtain a perpendicular eccentric distance of a corresponding one of the openings 4412 so as to determine the extent of perpendicular shifting of the heat sink 44 relative to the substrate 41. If the horizontal or perpendicular eccentric distance exceeds a predetermined value, it indicates that the heat sink 44 is shifted and not placed at a predetermined position on the substrate 41, and the shifting of the heat sink 44 may be corrected by moving the heat sink 44 or the substrate 41.

Referring to FIGS. 4G and 4H, FIG. 4H is a cross-sectional view of FIG. 4G taken along line 4H-4H. After the heat sink 44 is properly positioned on the substrate 41 or placed at the predetermined position on the substrate 41, an adhesive 4413 in advance applied to the substrate 41 is used to attach bottom surfaces of the supporting portions 441 (not having the openings 4412) of the heat sink 44 to the substrate 41. Before the adhesive 4413 is completely cured, if the heat sink 44 is shifted in position due to vibration from and improper operation of the process equipment, the checking system 5 shown in FIG. 4H can be used to inspect the extent of positional shifting between the openings 4412 of the heat sink 44 and the recognition points 411 on the substrate 41 in a real time manner, and the attachment of the heat sink 44 to the substrate 41 can be reworked if necessary. After the adhesive 4413 is heated and completely cured, a semiconductor package 4 of the present invention is accomplished wherein the chip 42 is mounted on and electrically connected to the substrate 41 by the gold wires 43 and is received in the space between the substrate 41 and the flat portion 442.

### Second Preferred Embodiment

FIG. 5 is a top view of a semiconductor package in accordance with a second preferred embodiment of the present invention.

The semiconductor package of the second embodiment is similar to that of the first embodiment, with a primary difference in that, in the second embodiment, recognition points 611 formed on a substrate 61 are shaped as crosses instead of round dots. The cruciform recognition points 611 are advantageous of having definite horizontal and perpendicular axes, which are favorable for determining horizontal and perpendicular shifting in position of a heat sink placed on the substrate.

It should be understood that the shape of the recognition points on the substrate in the present invention is not limited to a rounded dot or a cross, but the recognition points may alternatively be shaped as a rhombus, square, or triangle, etc. The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a semiconductor package, the method comprising the steps of:
providing a substrate and a heat sink, and placing the heat sink on the substrate, wherein the substrate is formed with recognition points thereon and the heat sink has openings through which the recognition points are exposed;
having a checking system inspect the recognition points on the substrate through the openings of the heat sink, so as to ensure that the heat sink is placed at a predetermined position on the substrate; and
attaching the heat sink to the substrate by an adhesive.

2. The method of claim 1, wherein the recognition points are formed by electroplating a metal on the substrate.

3. The method of claim 1, wherein the recognition points are shaped as round dots.

4. The method of claim 1, wherein the recognition points are shaped as crosses.

5. The method of claim 1, wherein the checking system is a charge coupled device (CCD).

6. The method of claim 1, wherein the heat sink comprises a flat portion, and supporting portions integrally connected to the flat portion and elevating the flat portion to a predetermined height.

7. The method of claim 6, wherein the openings are formed in the supporting portions of the heat sink.

8. The method of claim 6, wherein the substrate is mounted with a chip thereon, and the chip is electrically connected to the substrate and is received in a space between the substrate and the flat portion of the heat sink.

9. A semiconductor package comprising:
a substrate formed with recognition points thereon; and
a heat sink mounted on the substrate and having openings through which the recognition points on the substrate are exposed.

10. The semiconductor package of claim 9, wherein the recognition points comprise a metal electroplated on the substrate.

11. The semiconductor package of claim 9, wherein the recognition points are shaped as round dots.

12. The semiconductor package of claim 9, wherein the recognition points are shaped as crosses.

13. The semiconductor package of claim 9, wherein the heat sink comprises a flat portion, and supporting portions integrally connected to the flat portion and elevating the flat portion to a predetermined height.

14. The semiconductor package of claim 13, wherein the openings are formed in the supporting portions of the heat sink.

15. The semiconductor package of claim 13, further comprising a chip mounted on and electrically connected to the substrate, wherein the chip is received in a space between the substrate and the flat portion of the heat sink.
